(19) United States
(12) Patent Application Publication
(10) Pub. No.: US 2026/0144087 A1
(43) Pub. Date: May 21, 2026

(54) WETTABLE LEAD EDGES FOR INTEGRATED CIRCUIT DEVICES

(71) Applicant: TEXAS INSTRUMENTS INCORPORATED, DALLAS, TX (US)

(72) Inventors: Yuqi ZHANG, XINDU (CN); Qianyang LI, SHANGHAI (CN); Huo Yun DUAN, SC (CN); Qin PENG, CHENGDU (CN)

(21) Appl. No.: 18/953,232

(22) Filed: Nov. 20, 2024

(51) Int. Cl. H01L 23/495; H01L 21/48; H01L 21/56; H01L 23/31

(52) U.S. Cl. CPC H10W 70/421; H10W 70/048; H10W 70/457; H10W 74/014; H10W 74/111

(57) ABSTRACT

One example described herein includes an integrated circuit (IC) device. The IC device includes a leadframe including a pad and a plurality of leads extending outwardly away from the die pad to terminate in a leading edge thereof. The IC device includes an IC die on the pad. A mold compound can be provided over the die and a portion of the leadframe to define an IC package. The leads can extend outwardly from a periphery of the IC package to terminate in a leading edge, and the leading edge of at least one of the leads includes a notch.

### TECHNICAL FIELD

This description relates generally to wettable lead edges for integrated circuit devices.

### BACKGROUND

Integrated circuits (ICs) form the basis for modern computing, in which IC dies are fabricated based on etching and layering different materials. The IC dies are combined with conductive metal that forms ground pads and/or leads and are packaged in packaging material to form IC packages. The conductive metal for a set of semiconductor dies that correspond to multiple IC dies can be formed from a lead-frame sheet. The IC packages in the IC package block are thus mechanically separated (e.g., by a sawing process) to singulate the IC packages in a typical fabrication process. The surfaces that are cut, including on leads, tend to be non-wettable.

### SUMMARY

One example described herein relates to an integrated circuit (IC) device. The IC device includes a leadframe including a pad and a plurality of leads extending outwardly away from the die pad to terminate in a leading edge thereof. The IC device includes an IC die on the pad. A mold compound can be provided over the die and a portion of the leadframe to define an IC package. The leads can extend outwardly from a periphery of the IC package to terminate in a leading edge, and the leading edge of at least one of the leads includes a notch.

Another example described herein relates to an IC device. The IC device includes a leadframe including a respective lead extending outwardly away from each of the two pads to terminate in a leading edge thereof. An IC die is on the two pads. A mold compound can be over the die and a portion of the leadframe to define an IC package, and the leads extend outwardly from a periphery of the IC package to terminate in a leading edge thereof. Each of the leads includes a respective notch extending centrally into the leading edge thereof to define a sidewall surface of the respective notch. A conductive material can be on surfaces of the leads including on the sidewall surface of each respective notch.

Another example described herein relates to a method of making an IC device. The method includes attaching dies to respective pads distributed across a leadframe sheet. The method also includes covering each of the dies and a portion of the leadframe with a molding material to define respective package bodies. A plurality of leads extends from a periphery of each package body to terminate in distal portions thereof at an adjacent support bar of the leadframe sheet, and a hole extends through the distal portion of each of the leads. The method also includes separating respective packaged semiconductor devices from one another. The separating can include cutting through the support bar and a distal portion of the holes to separate the leads from the adjacent support bar and form a notch in a leading edge of at least some of the leads. Each notch can be defined by a proximal portion of the hole that extends through the respective lead.

Another example described herein relates to a leadframe sheet. The leadframe sheet includes a plurality of leadframes distributed across the leadframe sheet, in which the leadframes are coupled together by respective support bars. Each of the leadframes includes a pad adapted to be coupled to a respective pad of a die. A lead includes a proximal end, a distal end and a hole through a distal portion of the lead. The proximal end of the lead is coupled to the pad, the distal end is coupled to an adjacent support bar, and the hole extends through a central portion of the lead adjacent the distal end thereof and intersects a saw street of the adjacent support bar.

### BRIEF DESCRIPTION OF THE DRAWINGS

FIGS. 1 and 2 are top and bottom perspective views of an example IC device.

FIG. 3 is a plan view depicting example IC devices being formed on a portion of a leadframe sheet.

FIG. 4 is a plan view depicting the example IC devices of FIG. 3 after separation.

FIG. 5 is a plan view depicting another example of IC devices on a portion of a leadframe sheet.

FIG. 6 is a plan view depicting yet another example of IC devices on a portion of a leadframe sheet.

FIG. 7 is a plan view of another example IC device.

FIG. 8 is a plan view of yet another example IC device.

FIG. 9 is a photograph of a solder joint formed with an example IC device.

FIG. 10 is a plan view of an example leadframe sheet.

FIG. 11 is a flow diagram depicting an example method of forming an IC device.

### DETAILED DESCRIPTION

This description relates to wettable lead edges for integrated circuit (IC) devices as well as to IC devices including wettable lead edges and leadframe sheets that can be used to form such IC devices.

As an example, an IC device, a leadframe includes one or more pads (e.g., die pads or leads) and a plurality of leads extending outwardly away from the one or more pads to terminate in a leading edge thereof. An IC can be mounted on the pad, such that one or more pads of the die are coupled to respective pads of the leadframe. A mold compound is over the die and a portion of the leadframe to define an IC package. The leads extend outwardly from a periphery of the IC package and terminate in a leading edge thereof. Each of the leads includes opposing (e.g., top and bottom) surfaces spaced apart from each other by lateral sidewalls thereof. The particular arrangement and configuration of the leads can depend on the package type, which can be any leaded package type. For example, the leads can extend from one side (e.g., single in-line packages), from two sides (e.g., dual in-line packages, from four sides of the package (e.g., small outline packages, flat packages, small-outline transistor packages, etc.). One or more (e.g., each) of the leads includes a respective notch extending into the leading edge thereof. Each notch thus has a sidewall surface (e.g., recessed surface of the lead) that includes a plating of a conductive material disposed along at least a portion of the sidewall surface of the respective notch. A distalmost portion of the leading edge of one or more leads can be free of the plating of the conductive material such as due to cutting through the leads as part of the packaging process. The plating in the notch of the one or more leads provides a wettable lead edge. The wettable lead edge can improve bond reliability between the leads and substrate (e.g., printed circuit board (PCB) or another IC device) to which the IC device is coupled. Also, the wettable lead edge can facilitate visual inspection of solder joints between the leads and substrate.

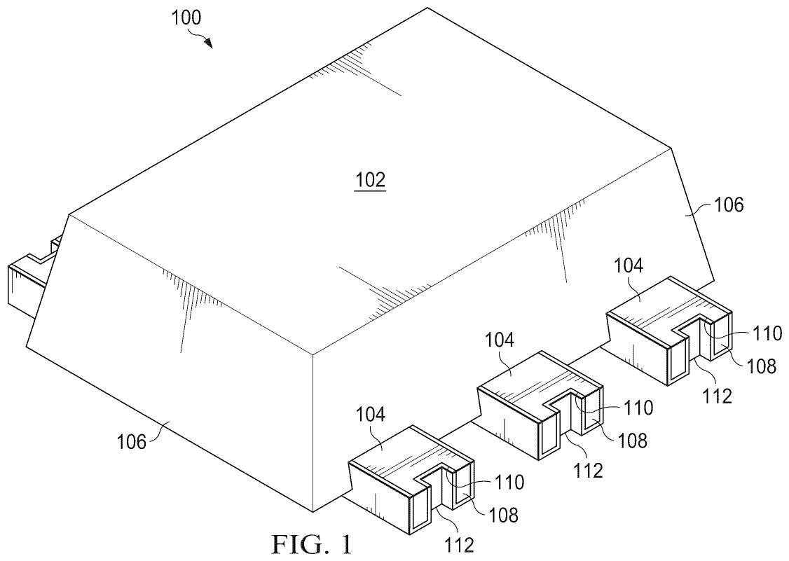

FIGS. 1 and 2 depict top and bottom perspective views of an example IC device 100. The IC device 100 includes a package body 102, which can include one or more IC dies therein (not shown), which can be attached to respective pads of a leadframe. For example, the pads can define die pads and/or leads of the respective leadframe. The package body 102 can be formed of a mold compound that is applied over the die and a portion of the leadframe to define the IC package body. A plurality of electrically conductive leads 104, which define part of the leadframe, extend outwardly from a periphery 106 the package body 102 to terminate in respective leading edges 108 thereof. The leading edge 108 of at least one of (e.g., each of) the leads 104 includes a notch 110 having a sidewall surface. For example, a rectangular (e.g., rectangular prism or cuboidal) shaped notch includes opposing planar surfaces connected by a back wall surface, in which the opposing planar surfaces are substantially parallel to surfaces of the lateral sides of lead. As used herein, a notch can refer to one or more recesses, grooves, channels or other voids in the leading edge of the lead, having any of a variety of shapes, that extends completely or partially through the lead (e.g., between top and bottom surfaces of the lead) and provides a receptacle configured to receive therein a conductive material, such as described herein.

A coating of a conductive material 112 is provided on surfaces of leads 104 including on the notch surfaces of the respective leads. The coating of the conductive material 112 can be on all surfaces (e.g., top, bottom, and side surfaces as well as a sidewall surface of the notch 110). Alternatively, the coating of the conductive material 112 can be selectively applied to a desired subset of surfaces, such as the bottom surface of the leads and the surface of the notch 110. The distal most edge of the leads 104 can define respective cut surfaces that are free of the coating of the conductive material. For example, the conductive material is a tin material (e.g., tin, tin-silver, tin-lead) that can be applied in a plating or other deposition process to coat the sidewall surfaces of the leads. The coating of the conductive material (e.g., tin plating) 112 helps to improve solderability when the IC device 100 is soldered to a substrate, such as a PCB or another IC device. The coating of the conductive material (e.g., tin plating) 112 can also help to improve bond reliability. Visual inspection (e.g., by automated tools or by human observers) of the resulting bonds can also be facilitated.

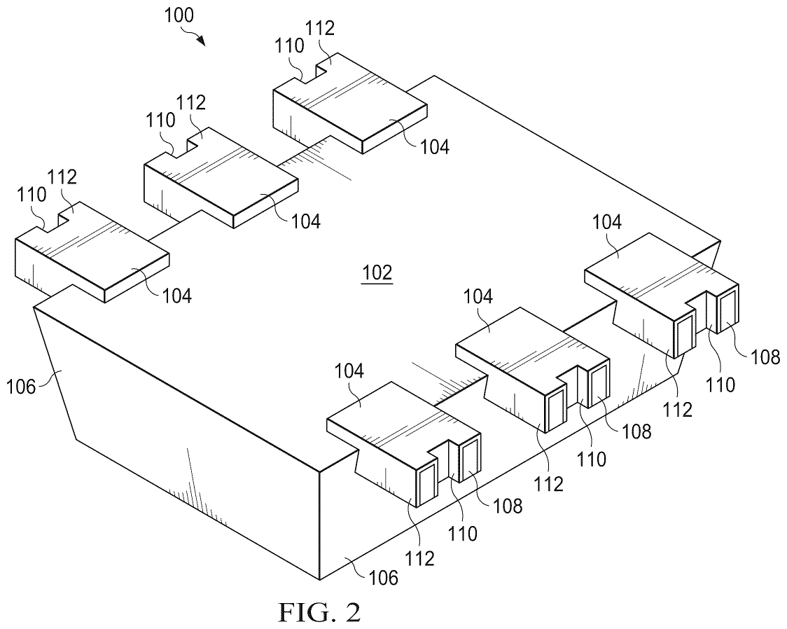

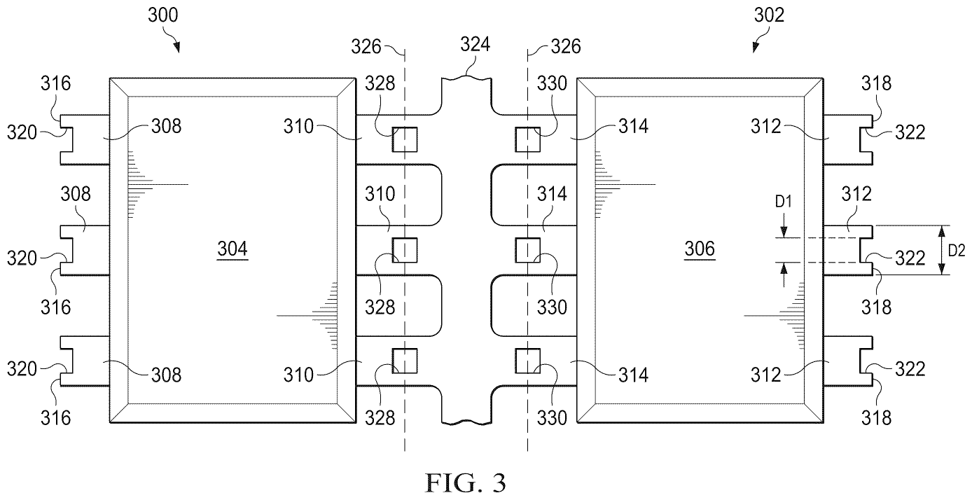

FIGS. 3 and 4 depict example IC devices 300, 302 being formed. In the example of FIGS. 3 and 4, a mold compound has been applied over one or more IC dies, which are mounted on respective pads of a leadframe sheet, to form package bodies 304 and 306 for the respective IC devices 300 and 302. FIG. 3 shows the IC devices 300 and 302 prior to being separated and FIG. 4 shows the IC devices after separation. The IC device 300 includes one group of leads 308 extending from one side of the package body 304 and another group of leads 310 extending from an opposing side of the package body 304. Similarly, the IC device 302 includes leads 312 extending from one side of the package body 306 and another group of leads 314 extending from an opposing side of the package body 306.

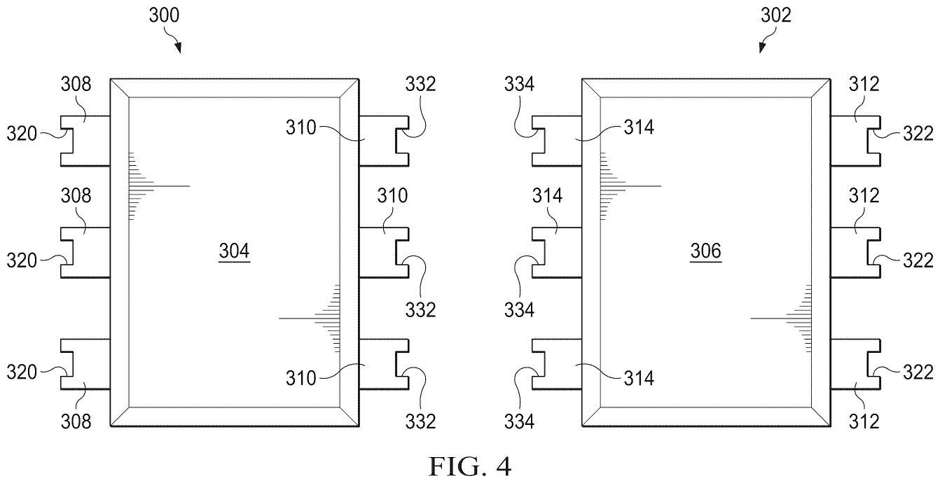

In the example of FIG. 3, the leads 308 and 312 terminate in respective leading edges 316 and 318. The leading edges 316 include notches 320 formed therein, and the leading edges 318 also include notches 322. Each of the notches 320, 322 can define a respective recess (or multiple recesses) that extends from a distalmost edge of the lead into the leading edge 316, 318 of the respective lead 308, 312 in a direction towards the periphery of the IC package body 304 and 306 from which the lead extends. In the example of FIGS. 3 and 4, the notches have a rectangular configuration. Other shape notches can be provided in other examples (see, e.g., FIGS. 5-8).

As shown in FIG. 3, prior to separation, the other leads 310 and 314 are coupled to each other through a support bar 324 of the leadframe, in which the support bar and distal end portions of the leads 310 and 314 can define a saw street, shown by dashed line 326, that extends between adjacent columns (or rows) of IC devices in the leadframe. Each of the leads 310 and 314 can include one or more holes 328 and 330, respectively, that extends through a central portion of the distal portion of the leads. In the example of FIG. 3, each lead includes a single hole 328, 330. In other examples, other numbers and/or configurations of holes can be used (see, e.g., FIGS. 5-8). The saw street 326 can intersect each of the holes 328 and 330, such that when the saw street is cut through (e.g., during device separation) a corresponding notch 332 and 334 is formed in the leading edge of the respective leads 310 and 314, as shown in FIG. 4. In the example of FIG. 3, the holes 328 and 330 are rectangular in shape and the saw street 326 intersects through a center of the respective holes. Other shaped holes can be used in other examples.

As described herein, a conductive material is provided (e.g., by plating with a tin material) on surfaces of the leads, including on a sidewall surface (e.g., an inner periphery) of the holes 328 and 330 prior to separation. Responsive to device separation by cutting through the saw street 326 (FIG. 3), the notches 332 and 334 are formed (FIG. 4). The other notches 320 and 322 likewise can be formed during separation. The notches 320, 332, 322, and 334 can extend completely through the leads 308, 310, 312, and 314, such as between top and bottom surfaces thereof as shown. Each of the notches 320, 332, 322, and 334 has a sidewall surface that extends between the top and bottom surfaces of the respective leads 308, 310, 312, and 314. The conductive material (e.g., tin material) is provided on the sidewall surface of the notches 320, 332, 322, and 334. Due to the separation of the IC devices 300 and 302, however, a distalmost portion of the leading edge of the respective leads define cut surfaces that are free of the conductive material. Thus, even though the leading edges of respective leads 308, 310, 312, and 314 are cut during device separation, a substantial portion of the leading edges, corresponding to the notches 320, 322, 332, and 334, still remain wettable due to the presence of such notches.

As shown in FIG. 3, each notch 322 has a rectangular shape. Each notch 322 has sidewalls spaced apart from each other by a first distance, which defines a width D1 of the notch, that approximates (or is equal to) one-half a width D2 of the respective lead between the sides thereof. The notch 322 extends into the leading edge a second distance, which defines a depth of the notch that is less than or approximates (or is equal to) D1 (the notch width). Each of notches 320, 322, 332, and 334 can have the same dimensions and configurations for each of the leads 308, 310, 312, and 314. The location of the proximal edges of the holes 328 and 330 along the respective leads 310 and 314 relative to the opposing edges of the saw street 326 will determine the depth of the notches 320, 322, 332, and 334.

FIG. 5 depicts example IC devices 500, 502 being formed from a leadframe sheet that can include a plurality of IC devices. Each of the IC devices 500, 502 includes a package body 504, 506. A first group of leads 508 extend from one side of the package body 504 and another group of leads 510 extending from an opposing side of the package body 504. The package body. Similarly, the IC device 502 includes leads 512 extending from one side of the package body 506 and another group of leads 514 extending from an opposing side of the package body 506. The leads 508 and 512 are shown in FIG. 5 as already including respective notches 511 and 513 in the leading edges of the respective leads.

In the example of FIG. 5, the leads 510 and 514 are coupled to each other by a support bar 516 of the leadframe sheet prior to separation of the IC devices 500 and 502. The support bar and distal end portions of the leads 510 and 514 can define a saw street, shown by dashed line 518, that extends between adjacent columns (or rows) of IC devices in the leadframe. A single elongated hole 520 extends centrally through a distal portion of each of the leads 510 and 514 and the saw street 518. This can be compared to the example of FIG. 3, in which separate holes 328 and 330 are provided for each of the respective leads 310 and 314, which are separated from each other by a connecting portion of the support bar 324. Responsive to device separation by cutting through the saw street 518, the notches are formed in the leads 510 and 514 of the separated IC devices, such as the separated IC devices shown in the example of FIG. 4. The other leads 508 and 512 similarly include notches 522, which can be formed by cutting through respective holes (e.g., instances of holes 520) during separation. As described herein, prior to separation, a layer of a conductive material (e.g., plating of a tin material) can be applied to the surface of the leads 508, 510, 512, and 514, including the inner periphery of the holes 520. As a result of device separation, the surface of the notches 522 includes the applied conductive material while a distalmost portion of the leading edge of each of the leads can define a cut surface that is free of the conductive material.

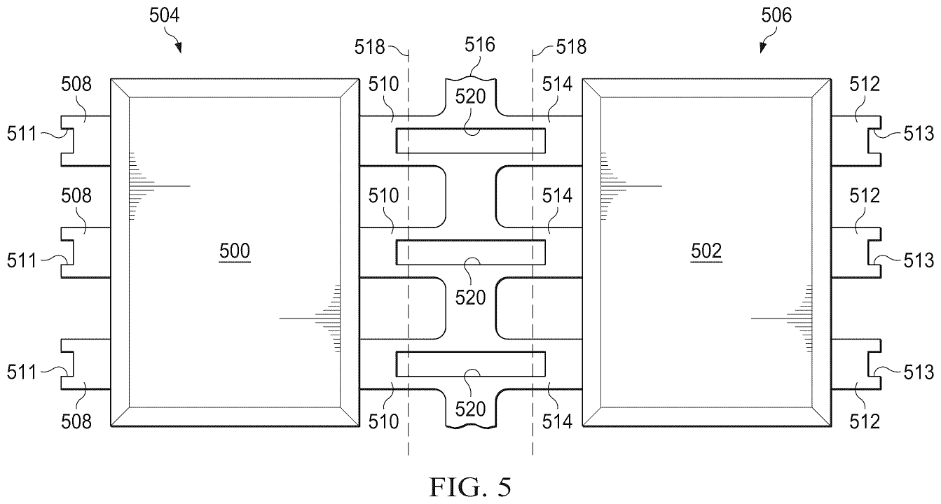

FIGS. 6, 7, and 8 demonstrate examples of some different configurations of notches that can be formed in the leading edges of leads. The examples shown are not exhaustive but are for the purpose of showing that various different numbers of notches and/or shapes of notches can be implemented. As described herein, the different notches can result from separation of IC devices from a leadframe sheet by cutting through corresponding holes having the desired shapes for the notches being formed. Also, the resulting notches as well as other portions of the leads can include a coating of a conductive material (e.g., plating of a tin material), which can be applied prior to separation, as described herein.

FIG. 6 depicts another example of IC devices 600 and 602 on a portion of a leadframe sheet prior to separation thereof, in which multiple notches 604 and 605 are formed in the leading edge of respective leads 606 and 610 (and will be formed in leads 608 and 612 responsive to separation). FIG. 6 thus demonstrates that there can be more than one notch in each lead 606, 608, 610, and 612. Each of the leads 606, 608, 610, and 612 extends from a respective package body 613 and 614 (e.g., molding compound), which covers one or more dies attached to the leadframe. Also, while the example of FIG. 6 includes three rectangular shaped notches 604 and 605 in the respective leads 606 and 610, other shapes and/or numbers of notches can be provided in other examples.

In the example of FIG. 6, the leads 608 and 612 are coupled to each other through a support bar 616 of the leadframe sheet that prior to separation of the IC devices 600 and 602. The support bar 616 and distal end portions of the leads 608 and 612 can define a saw street 618 that extends between adjacent columns (or rows) of IC devices in the leadframe, which includes the IC devices 600 and 602. Respective groups of holes 620 and 622 are provided through distal end portions of each of the respective leads 608 and 612. The holes 620 and 622 also extend into the saw street 618 so that, responsive to separation by cutting through the saw street, corresponding notches (like notches 604 and 605) will be formed in the leading edge of the respective leads 608 and 612. Further, prior to separation, the surfaces of the leads 606, 608, 610, and 612 and surfaces of the holes 620 and 622 (as well as other holes through the lead sheet- not shown) can include a coating of a conductive material (e.g., plating of a tin material). As described herein, the coating of conductive material remains on the surfaces of leads, including on the surfaces of the resulting notches, after separation. The distalmost surface, defining a cut surface (e.g., cut during separation) can be free of the conductive material.

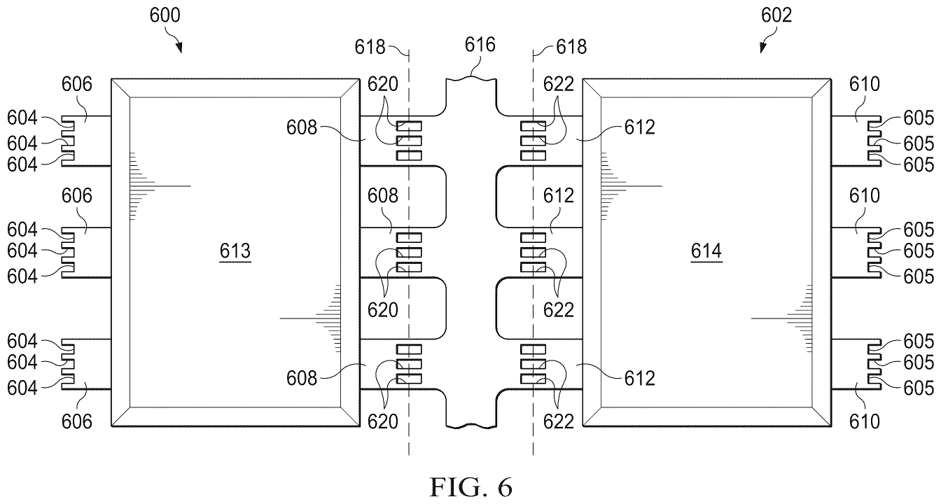

FIG. 7 depicts another example IC device 700 that includes curved notches (e.g., semicircular or C-shaped notches) 702 in leading edges 704 of respective leads 706. The leads 706 can extend outwardly from one or more sides of a package body 708 that contains one or more IC dies. The curved notches 702 can be formed, for example, by cutting through a saw street that extends through a distal portion of leads through which circular or elliptical holes extend, such as described herein. Also, surfaces of the leads 706 and surfaces of the notches 702 can include a coating of a conductive material (e.g., plating of a tin material), which can be applied prior to separation. Further, the coating of conductive material remains on the surfaces of leads, including on the surfaces of the resulting notches, after separation. The distalmost surfaces of the leading edge 704 of the leads, defining cut surfaces on opposing sides of the notch (e.g., cut during separation), can be free of the conductive material.

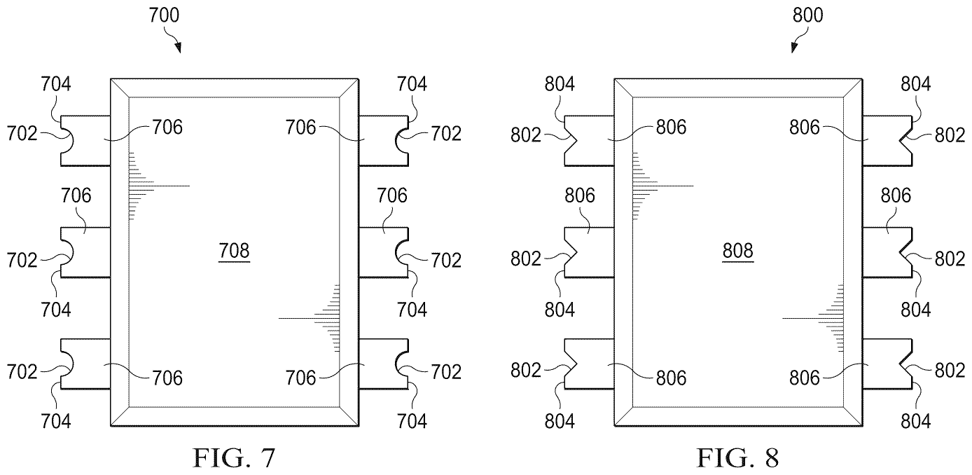

FIG. 8 depicts yet another example IC device 800 that includes V-shaped notches (e.g., 802 in leading edges 804 of respective leads 806. The leads 806 can extend outwardly from one or more sides of a package body 808 that contains one or more IC dies. The V-shaped notches 802 can be formed, for example, by cutting through a saw street that extends (e.g., orthogonally) through a distal portion of leads that include rectangular- or diamond-shaped lead holes, such as described herein. Also, surfaces of the leads 806 and surfaces of the notches 802 can include a coating of a conductive material (e.g., plating of a tin material), which can be applied prior to separation. Further, the coating of conductive material remains on the surfaces of leads 806, including on the surfaces of the resulting notches 802, after separation. The distalmost surfaces of the leading edge 804 of the leads 806 can define cut surfaces on opposing sides of the notch (e.g., cut during separation), which may be free of the conductive material.

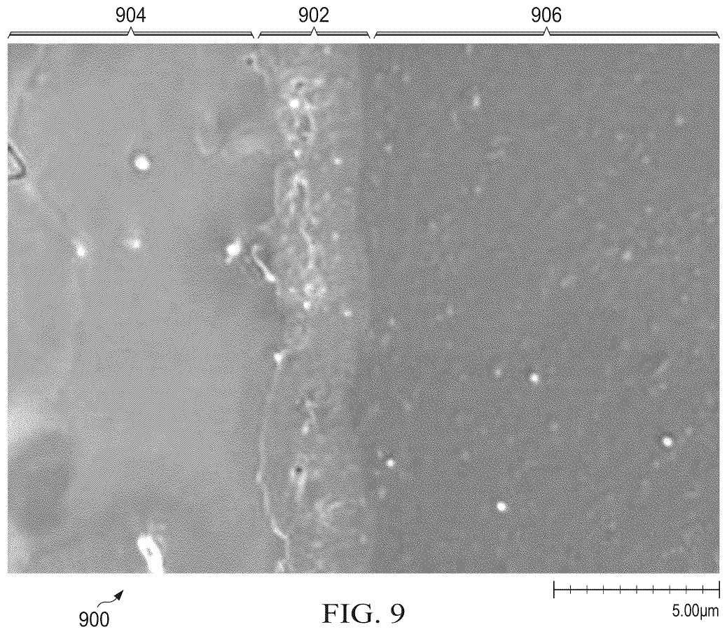

FIG. 9 is a photograph 900 depicting a solder joint formed with an example IC device. The solder joint includes a region of solder 902, a region of copper 904 and an intermetallic compound (IMC) layer 906 that includes tin (e.g., tin-copper, tin-silver, etc.).

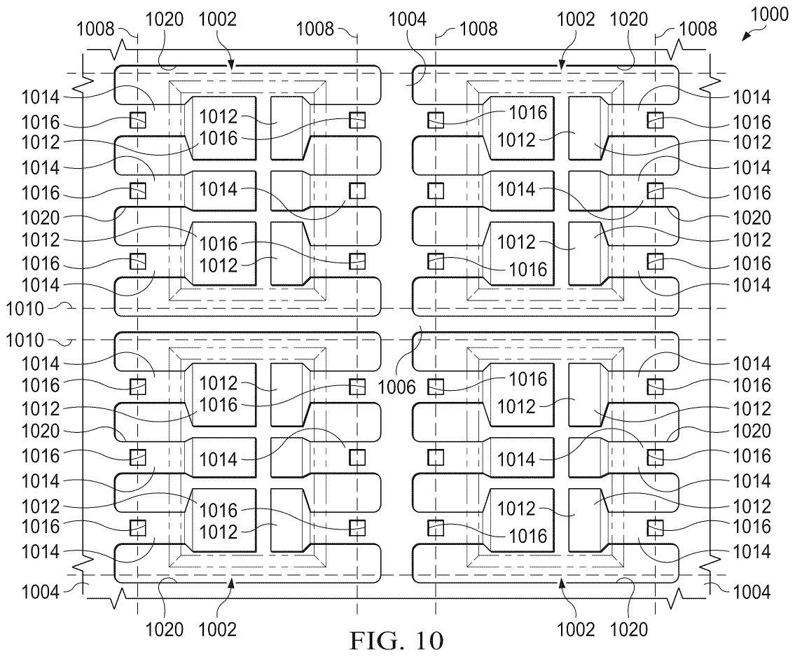

FIG. 10 is a plan view of an example leadframe sheet 1000. The leadframe sheet 1000 includes a plurality of leadframes 1002 distributed across the leadframe sheet (e.g., in a number of rows and columns, which can depend on the size of the sheet and the size of the individual leadframes. The leadframes 1002 are coupled together by respective support bars 1004 and 1006, which can extend between respective rows and columns of the leadframes. In the example of FIG. 10, the support bars 1004 and 1006 are oriented orthogonally relative to each other and can extend between edges of the leadframe sheet 1000. Each of the support bars 1004 and 1006 can reside within respective saw streets, shown at 1008 and 1010.

In the example of FIG. 10, each of the leadframes 1002 includes one or more pads 1012. Each of the pads 1012 can be a lead pad that is coupled to a respective lead (e.g., for supporting a chip-on-lead IC device), which can be adapted to be coupled to one or more respective pads of an IC die. In other examples, the leadframes 1002 can be configured for other types of IC devices and include one or more pads (e.g., die pads and/or leads) configured and arranged according to the IC package that is to be formed. As a further example, each lead 1014 includes proximal and distal end portions. The leadframe also includes a hole extending through the distal end portion of each of the leads, in which the proximal end is coupled to the pad, the distal end is coupled to an adjacent support bar, and the hole extends through a central portion of the lead and intersects a saw street of the adjacent support bar.

The leadframe sheet 1000 can be a conductive structure of a conductive material (e.g., copper, copper-alloy, iron-nickel alloy or similar materials), which can be formed by removing material around the leads, pads, as well as other interconnects or features. Each of the leadframes also includes cut-out regions 1020 surrounding the respective pads 1012 and leads 1014. Each of the holes 1016 and cut-out regions 1020 can be formed through the leadframe sheet by removing the conductive material (e.g., by wet etching, dry etching, plasma etching, etc.), laser cutting, saw cutting, punching, grinding, drilling, or other methods.

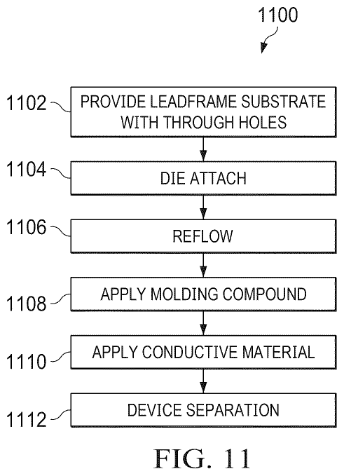

In view of the foregoing structural and functional features described above, FIG. 11 is a flow diagram showing an example method for making one or more IC devices. While, for purposes of simplicity of explanation, the method of FIG. 11 is shown and described as executing serially, it is to be understood and appreciated that the method 1100 is not limited by the illustrated order. Moreover, not all illustrated features may be required to implement the method 1100.

FIG. 11 is a flow diagram depicting an example method 1100 of forming an IC device, such as any of the IC devices 100, 302, 304, 600, 502, 600, 602, 700, and/or 800 described herein. Accordingly, the description of FIG. 11 can refer to certain aspects of FIGS. 1-8 and 10.

At 1102, the method 1100 includes providing a leadframe substrate (e.g., leadframe sheet 1000) that includes a plurality of leadframes. The leadframes include through holes (e.g., holes 328, 330, 520, 620, 622, 1016 through one or more leads). At 1104, the method includes attaching dies to respective leadframes distributed across the leadframe sheet. For example, a die includes one or more pads that are coupled to one or more pads responsive to the die attachment at 1104. At 1106, the method includes performing reflow to secure the dies to the pads of the leadframes, which can electrically couple the pads coupled to respective leads of the leadframe.

At 1108, the method includes applying a molding material (e.g., an epoxy or plastic material) to cover each of the dies and a portion of the leadframe with the molding material and define respective package bodies. The plurality of leads (e.g., leads 308, 310, 312, 314, 508, 510, 512, 514, 606, 608, 610, 612, 706, 806, and/or 1014) extend from a periphery of each package body (e.g., package body 102, 304, 306, 504, 506, 613, 614, 708, 808) to terminate in distal portions thereof at an adjacent support bar of the leadframe sheet. As described herein, each leadframe includes a hole (e.g., one or more holes 328, 330, 520, 620, 622, 1016) that extends through the distal portion of each of the leads (e.g., leads 308, 310, 312, 314, 508, 510, 512, 514, 606, 608, 610, 612, 706, 806, and/or 1014).

At 1110, the method includes applying a conductive material on surfaces of the leads (e.g., leads 308, 310, 312, 314, 508, 510, 512, 514, 606, 608, 610, 612, 706, 806, and/or 1014) including on an inner periphery of the holes (e.g., one or more holes 328, 330, 520, 620, 622, 1016). For example, the conductive material (e.g., tin, tin-silver, tin-lead, gold,) can be applied in a plating process following the application of the molding compound. After applying the conductive material at 1110, the plated leadframe sheet can be trimmed and/or cleaned to remove excess conductive material. While the plating is described in examples herein as occurring after the molding compound has been applied, in other examples, the conductive material can be applied at other stages of the method including when the leadframe is made. For example, the conductive material (e.g., tin material or nickel-palladium or nickel-palladium-gold, etc.) can be applied as a pre-plated finish, and thus already exist on the leadframe (e.g., on the leads and inner peripheries of holes) that is provided at 1102.

At 1112, the method includes performing device separation. For example, respective packaged IC devices (e.g., IC devices 100, 300, 302, 500, 502, 600, 602, 700, 800) are separated from one another, such as by cutting along respective saw streets through the support bar and a distal portion of the holes to separate the leads from the adjacent support bar and form a notch (e.g., notches 110, 320, 322, 332, 334, 511, 513, 604, 605, 702, 802) in a leading edge of at least some of (e.g., all of) the leads. Each notch can be a recess in the leading edge of the respective lead, which is defined by a proximal portion of the hole that extends through the respective lead. Responsive to separating, the conductive material (e.g., plating) can remain on an inner periphery of the notch, and the leading edge of the respective lead includes a distalmost cut surface that is free of the conductive material.

In this description, numerical designations “first”, “second”, etc. are not necessarily consistent with same designations in the claims herein and these numerical designations are used to simply distinguish one element from another.

Additionally, the term “couple” or variants thereof may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A. In this description, the term “based on” means based at least in part on.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Unless otherwise stated, “about,” “approximately,” or “substantially” preceding a value means within +/−10 percent of the stated value, or, if the value is zero, a reasonable range of values around zero.

Modifications are possible in the described embodiments, and other embodiments are possible, within the scope of the claims.

What is claimed is:

1. An integrated circuit (IC) device, comprising:
a leadframe including a pad and a plurality of leads extending outwardly away from the pad to terminate in a leading edge thereof;
an IC die on the pad; and
mold compound over the IC die and a portion of the leadframe to define an IC package, wherein the leads extend outwardly from a periphery of the IC package to terminate in a leading edge, and the leading edge of at least one of the leads includes a notch.

2. The IC device of claim 1, further comprising a plating of a conductive material on surfaces of leads including on a surface of the respective notch.

3. The IC device of claim 2, wherein the conductive material comprises a tin material.

4. The IC device of claim 2, wherein the leading edge of each of the plurality of leads includes a respective notch.

5. The IC device of claim 3, wherein:
the at least one lead includes opposing surfaces spaced apart from each other by a sidewall portion,
the notch extends a distance into the leading edge of the at least one of the leads in a direction towards the IC package and completely through the opposing surfaces of the at least one of the leads to define the surface of the respective notch, and
the plating of the conductive material is disposed along at least a portion of the surface of the respective notch extending between the opposing surfaces of the at least one of the leads.

6. The IC device of claim 5, wherein a distalmost portion of the leading edge of the at least one of the leads is free of the plating of the conductive material.

7. The IC device of claim 1, wherein the notch includes a sidewall extending into the leading edge of the at least one of the leads having a rectangular shape, a V-shape, or a semi-circular shape.

8. The IC device of claim 1, wherein the at least one of the leads includes sides that extend from the periphery of the IC package to terminate in the leading edge, the sides are spaced apart from each other by opposing top and bottom surfaces of the at least one of the leads, the notch extends from a distalmost portion of the leading edge of the at least one of the leads centrally between the sides thereof the at least one of the leads.

9. The IC device of claim 8, wherein the notch has sidewalls spaced apart from each other by a first distance that approximates one-half a width of the at least one of the leads between the sides of the at least one of the leads, and the notch extends from the leading edge a second distance that is less than the first distance.

10. The IC device of claim 9, wherein the sidewalls of the notch define respective surfaces that are substantially parallel to surfaces of the sides of the at least one of the leads.

11. An integrated circuit (IC) device, comprising:
a leadframe including at least two pads and a respective lead extending outwardly away from each of the two pads to terminate in a leading edge thereof;
an IC die on the at least two pads;
mold compound over the IC die and a portion of the leadframe to define an IC package, wherein the leads extend outwardly from a periphery of the IC package and terminate in a leading edge thereof, and each of the respective leads includes a respective notch extending centrally into the leading edge thereof to define a sidewall surface of the respective notch; and
a plating of a conductive material on surfaces of the leads including on the sidewall surface of each respective notch.

12. The IC device of claim 11, wherein the conductive material comprises a tin material.

13. The IC device of claim 11, wherein:
each of the leads includes opposing surfaces spaced apart from each other by lateral sidewalls, and
each of the notches extends completely through the opposing surfaces of the respective lead to define the sidewall surface of each respective notch.

14. The IC device of claim 13, wherein the sidewall surface of each notch at the leading edge of each respective lead includes opposing sidewall portions that are spaced apart from each other by a first distance that is less than or equal to one-half a width of the respective lead between the lateral sidewalls thereof, and the notch extends into the leading edge a second distance that is less than the first distance.

15. The IC device of claim 11, wherein each notch has a rectangular shape, a semi-circular shape, or a V-shape into the leading edge of the respective lead between lateral sidewalls of the respective lead.

16. The IC device of claim 13, wherein the sidewall surface of each notch is substantially parallel the lateral sidewalls of respective lead.

17. The IC device of claim 11, wherein a distalmost portion of the leading edge of each of the leads is free of the plating of the conductive material.

18. A method of making an IC device, comprising:
attaching dies to respective pads distributed across a leadframe sheet;
covering each of the dies and a portion of the leadframe with a molding material to define respective package bodies, in which a plurality of leads extends from a periphery of each package body to terminate in distal portions thereof at an adjacent support bar of the leadframe sheet, and a hole extends through the distal portion of each of the leads; and
separating respective packaged semiconductor devices from one another, in which the separating includes cutting through the adjacent support bar and a distal portion of the holes to separate the leads from the adjacent support bar and form a notch in a leading edge of at least some of the leads, and each notch is defined by a proximal portion of the hole that extends through the respective lead.

19. The method of claim 18, wherein, prior to separating, a conductive material is applied on surfaces of the leads including on an inner periphery of the holes.

20. The method of claim 19, wherein, after separating, the conductive material remains on an inner periphery of the notch, which is defined by the proximal portion of the hole, and the leading edge of the respective lead defines a distalmost cut surface that is free of the conductive material.

21. The method of claim 19, wherein the conductive material comprises a tin material and is plated on surfaces of the leads including the inner periphery of the holes.

22. A leadframe sheet comprising:
a plurality of leadframes distributed across the leadframe sheet in which the leadframes are coupled together by respective support bars, and each of the leadframes comprises:
a pad adapted to be coupled to a respective pad of a die; and
a lead including a proximal end, a distal end and a hole through a distal portion of the lead, in which the proximal end is coupled to the pad, the distal end is coupled to an adjacent support bar, and the hole extends through a central portion of the lead adjacent the distal end thereof and intersects a saw street of the adjacent support bar.
